(19) United States
(12) Patent Application Publication
(10) Pub. No.: US 2017/0301514 A1
(43) Pub. Date: Oct. 19, 2017

(54) PLASMA SOURCE AND SUBSTRATE TREATING APPARATUS INCLUDING THE SAME

(71) Applicant: PSK INC., Gyeonggi-do (KR)

(72) Inventors: Jeong Hee CHO, Gyeonggi-do (KR); Han Saem RHEE, Gyeonggi-do (KR); Saad NAWAZ, Gyeonggi-do (KR)

(21) Appl. No.: 15/218,281

(22) Filed: Jul. 25, 2016

(30) Foreign Application Priority Data
Apr. 19, 2016 (KR) 10-2016-0047698

(51) Int. Cl. H01J 37/32

(52) U.S. Cl. CPC H01J 37/3211; H01J 37/32651; H01J 37/32449; H01J 2237/334

(57) ABSTRACT

An apparatus for treating a substrate includes a process chamber with a treatment space, a substrate support unit that supports the substrate, a gas supply unit that supplies a gas into the treatment space, and a plasma source that excites the gas into plasma, the process chamber includes a discharge chamber that is provided over the substrate support unit and has a space in which the gas is excited into the plasma, and the plasma source includes an antenna including a first coil and a second coil that surround a side surface of the discharge chamber along a circumference of the discharge chamber, and a power supply that applies electric power to the antenna, wherein the first coil and the second coil are alternately arranged along a vertical direction, and when viewed from the top, currents flow through the first coil and the second coil in the same direction.

### CROSS-REFERENCE TO RELATED APPLICATIONS

A claim for priority under 35 U.S.C. §119 is made to Korean Patent Application No. 10-2016-0047698 filed Apr. 19, 2016, in the Korean Intellectual Property Office, the entire contents of which are hereby incorporated by reference.

### BACKGROUND

The inventive concept relates to a substrate treating apparatus, and more particularly to an apparatus for treating a substrate by using plasma.

Various processes such deposition, photography, etching, ashing, cleaning, and polishing are required on a semiconductor substrate such as a wafer in order to manufacture a semiconductor device. Among them, in many processes such as deposition, etching, and ashing, a semiconductor substrate such as a wafer is treated by using plasma or a gas.

In the case of an inductively coupled plasma (ICP) source of the plasma sources that generates plasma to treat a substrate, plasma generating efficiency becomes higher as the intensity of a magnetic field due to electric power applied to an antenna becomes stronger. However, when a high voltage is applied to an antenna to increase the intensity of a magnetic field, the intensity of an electric field becomes stronger so that an area of the inner surface of a chamber, in which plasma is generated, may be damaged by sputtering. This causes particles that influence a process.

### SUMMARY

The inventive concept provides an apparatus for minimizing damage to a chamber by plasma.

The inventive concept also provides an apparatus for restraining generation of particles.

The inventive concept also provides an apparatus for increasing an efficiency of generating plasma.

The technical objects of the inventive concept are not limited to the above-mentioned ones, and the other unmentioned technical objects will become apparent to those skilled in the art from the following description.

The inventive concept provides an apparatus for treating a substrate. The apparatus includes a process chamber that has a treatment space for treating the substrate in the interior thereof, a substrate support unit that supports the substrate in the treatment space, a gas supply unit that supplies a gas into the treatment space, and a plasma source that excites the gas supplied by the gas supply unit into plasma, the process chamber includes a discharge chamber that is provided over the substrate support unit and has a space in which the gas is excited into the plasma, and the plasma source includes an antenna including a one first coil and a second coil that surround a side surface of the discharge chamber along a circumference of the discharge chamber, and a power supply that applies electric power to the antenna, and the first coil and the second coil are alternately arranged along a vertical direction, and when viewed from the top, currents flow through the first coil and the second coil in the same direction.

The power supply may apply electric power to a first end of the first coil and a first end of the second coil.

A second end of the first coil and a second end of the second coil may be grounded.

The plasma source may further include a connector that is connected to the first end of the first coil and the first end of the second coil to distribute electric power applied from the power source to the first coil and the second coil.

Capacitors may be provided at the second end of the first coil and the second end of the second coil, respectively, and the first coil and the second coil may be grounded through the capacitors.

The first end of the first coil may be situated to be higher than the second end of the first coil, and the first end of the second coil may be situated to be higher than the second end of the second coil.

The first end of the first coil may be situated to be lower than the second end of the first coil, and the first end of the second coil may be situated to be lower than the second end of the second coil.

The first end of the first coil may be situated to be higher than the second end of the first coil, and the first end of the second coil may be situated to be lower than the second end of the second coil.

The first end of the first coil may be situated to be lower than the second end of the first coil, and the first end of the second coil may be situated to be higher than the second end of the second coil.

The first coil may include a plurality of coils and The second coil may include a plurality of coils.

The apparatus may further include a Faraday shield that is provided between the discharge chamber, and the first coil and the second coil.

The inventive concept provides a plasma source for exciting a gas supplied into a treatment space in which a substrate is treated into plasma. The plasma source includes an antenna including a first coil and a second coil that surround a side surface of a discharge chamber along a circumference of the discharge chamber having a space for exciting the gas into plasma in the interior thereof, and a power supply that applies electric power to the antenna, and the first coil and the second coil are alternately arranged along a vertical direction, and when viewed from the top, currents flow through the first coil and the second coil in the same direction.

The power supply may apply high-frequency electric power to a first end of the first coil and a first end of the second coil.

A second end of the first coil and a second end of the second coil may be grounded.

The plasma source may further include a connector that is connected to the first end of the first coil and the first end of the second coil to distribute electric power applied from the power source to the first coil and the second coil.

Capacitors may be provided at the second end of the first coil and the second end of the second coil, respectively, and the first coil and the second coil may be grounded through the capacitors.

The first end of the first coil may be situated to be higher than the second end of the first coil, and the first end of the second coil may be situated to be higher than the second end of the second coil.

The first end of the first coil may be situated to be lower than the second end of the first coil, and the first end of the second coil may be situated to be lower than the second end of the second coil.

The first end of the first coil may be situated to be higher than the second end of the first coil, and the first end of the second coil may be situated to be lower than the second end of the second coil.

The first end of the first coil may be situated to be lower than the second end of the first coil, and the first end of the second coil may be situated to be higher than the second end of the second coil.

The inventive concept provides an apparatus for treating a substrate. The apparatus includes a process chamber that has a treatment space for treating the substrate in the interior thereof, a substrate support unit that supports the substrate in the treatment space, a gas supply unit that supplies a gas into the treatment space, and a plasma source that excites the gas supplied by the gas supply unit into plasma, the process chamber includes a discharge chamber that is provided over the substrate support unit and has a space in which the gas is excited into the plasma, the plasma source includes an antenna including a first coil and a second coil that surround a side surface of the discharge chamber along a circumference of the discharge chamber, and a power supply that applies electric power to the antenna, the first coil surrounds a side surface of the discharge chamber while extending from a first end to a second end thereof, the second coil surrounds a side surface of the discharge chamber while extending from a first end to a second end thereof, and the first coil and the second coil surrounds a side surface of the discharge chamber in the same direction when viewed form the top, and the electric power of the power supply is applied from the first end of the first coil and the first end of the second coil.

The plasma source may further include a connector that is connected to the first end of the first coil and the first end of the second coil to distribute the electric power of the power source to the first coil and the second coil.

The second end of the first coil and the second end of the second coil may be grounded.

Capacitors may be provided at the second end of the first coil and the second end of the second coil, respectively, and the first coil and the second coil may be grounded through the capacitors.

The first end of the first coil may be situated to be higher than the second end of the first coil, and the first end of the second coil may be situated to be higher than the second end of the second coil.

The first end of the first coil may be situated to be lower than the second end of the first coil, and the first end of the second coil may be situated to be lower than the second end of the second coil.

The first end of the first coil may be situated to be higher than the second end of the first coil, and the first end of the second coil may be situated to be lower than the second end of the second coil.

The first end of the first coil may be situated to be lower than the second end of the first coil, and the first end of the second coil may be situated to be higher than the second end of the second coil.

The first coil may include a plurality of coils and the second coil may include a plurality of coils, and the coils of the first coil and the coils of the second coil may be provided to be alternately arranged in a vertical direction.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a substrate treating apparatus 1 according to an embodiment of the inventive concept;

FIG. 2 is a plan view of a first coil of FIG. 1 when viewed from the top;

FIG. 3 is a plan view of a second coil of FIG. 1 when viewed from the top;

FIG. 4 is a perspective view schematically illustrating the plasma source of FIG. 2; and

FIGS. 5 to 8 are perspective view illustrating plasma sources according to other embodiments.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

In an embodiment of the inventive concept, a substrate 10 may be a semiconductor wafer. However, the inventive concept is not limited thereto, and the substrate 10 may be another type of substrate such as a glass substrate.

Further, in the embodiment of the inventive concept, a substrate treating apparatus may be an apparatus that performs a process such as ashing, deposition, or etching by using plasma.

Hereinafter, the substrate treating apparatus 1 according to an embodiment of the inventive concept will be described.

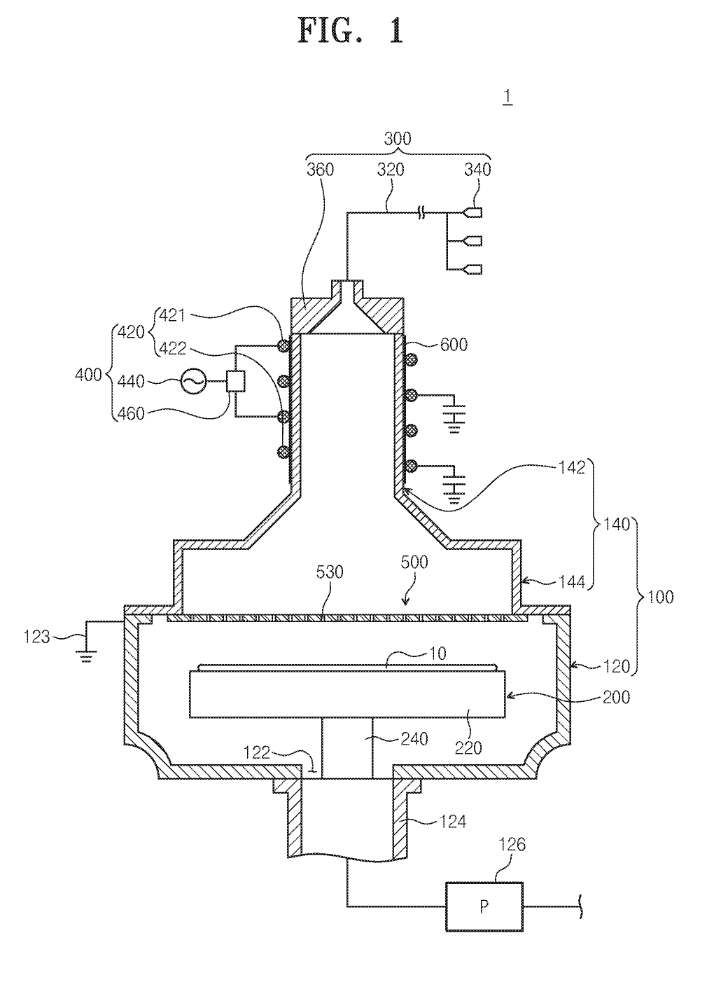

FIG. 1 is a sectional view illustrating a substrate treating apparatus 1 according to an embodiment of the inventive concept. Referring to FIG. 1, the substrate treating apparatus 1 has a process chamber 100, a substrate support unit 200, a gas supply unit 300, a plasma source 400, and a baffle 500.

The process chamber 100 has a treatment space in which a substrate is treated. According to an embodiment, the process chamber 100 has a treatment chamber 120 and a plasma generating chamber 140. The treatment chamber 120 provides a space in which the substrate 10 is treated by plasma. The plasma generating chamber 140 provides a space in which plasma is generated from a gas.

The treatment chamber 120 has a space, of which the upper side is opened, in the interior thereof. The treatment chamber 120 may have a substantially cylindrical shape. A substrate introducing hole (not illustrated) is formed in a side wall of the treatment chamber 120. The substrate 10 enters and exits from the interior of the treatment chamber 120 through the substrate introducing hole. The substrate introducing hole (not illustrate) may be opened and closed by an opening/closing member such as a door (not illustrated). An exhaust hole 122 is formed on the bottom surface of the treatment chamber 120. An exhaust line 124 is connected to the exhaust hole 122. A pump 126 is installed in the exhaust line 124. The pump 126 adjusts a pressure in the process chamber 120 to a process pressure. Residual gases and reaction by-products in the treatment chamber 120 are discharged to the outside of the treatment chamber 120 through the exhaust line 124.

The plasma generating chamber 140 has a discharge chamber 142 and a diffusion chamber 144. The plasma generating chamber 140 is situated outside the treatment chamber 120. According to an embodiment, the plasma generating chamber 140 is situated over the treatment chamber 120 and coupled to the treatment chamber 120. Accordingly, the discharge chamber 142 and the diffusion chamber 144 may be provided over the substrate support unit 200. The discharge chamber 142 and the diffusion chamber 144 are sequentially provided in a vertical direction. The discharge chamber 142 has a hollow cylindrical shape. When viewed from the top, the space in the discharge chamber 142 may be narrower than the space in the treatment chamber 120. Plasma is generated from the gas supplied by the gas supply unit 300 in a space of the discharge chamber 142. The space in the diffusion chamber 144 has a part that becomes gradually wider as it goes downwards. A lower end of the diffusion chamber 144 is coupled to an upper end of the treatment chamber 120, and a sealing member (not illustrated) is provided between the diffusion chamber 144 and the treatment chamber 120 for sealing from the outside.

The process chamber 100 is formed of a conductive material. The process chamber 100 may be grounded through a ground line 123.

The substrate support unit 200 supports the substrate 10 in the treatment space of the process chamber 100. According to an embodiment, the substrate support unit 200 has a support plate 200 and a support shaft 240.

The support plate 220 is situated in the treatment chamber 120 and has a disk shape. The support plate 220 is supported by the support shaft 240. The substrate 10 is positioned on an upper surface of the support plate 220. An electrode (not illustrated) may be provided in the interior of the support plate 220, and the substrate 10 may be supported by the support plate 220 through an electrostatic force or a mechanical clamp.

The gas supply unit 300 supplies a gas from the top of the baffle 500 into the treatment space of the process chamber 100. According to an embodiment, the gas supply unit 300 supplies the gas from the top of the discharge chamber 142. One or a plurality of gas supply units 300 may be provided. The gas supply unit 300 has a gas supply line 320, a gas storage 340, and a gas port 360.

The gas supply line 320 is connected to the gas port 360. The gas port 360 is coupled to the top of the discharge chamber 142. The gas supplied through the gas port 360 is introduced into the discharge chamber 142, and is excited into plasma in the discharge chamber 142.

A plasma source 400 generates plasma from the gas supplied by the gas supply unit 300 in the discharge chamber 142. The plasma source 400 is an inductively coupled plasma source. The plasma source 400 has an antenna 420, a power supply 440, and a connector 460.

The antenna 420 includes a first coil 421 and a second coil 422.

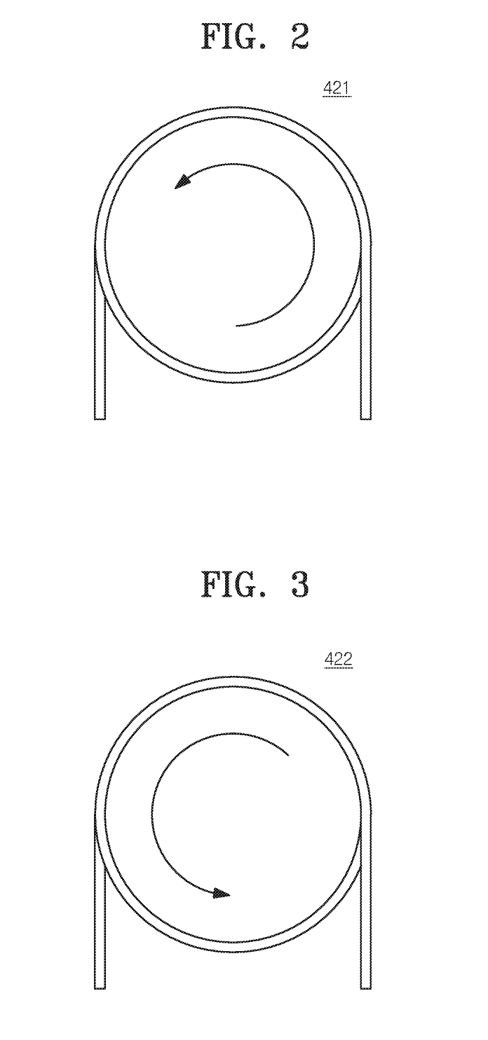

The first coil 421 and the second coil 422 surround a side surface of the discharge chamber 142 along a circumferential direction of the discharge chamber 142. The first coil 421 and the second coil 422 are alternately arranged in a vertical direction. FIG. 2 is a plan view of the first coil 421 of FIG. 1 when viewed from the top. FIG. 3 is a plan view of the second coil 422 of FIG. 1 when viewed from the top. Referring to FIGS. 2 and 3, when viewed from the top, currents flow through the first coil 421 and the second coil 422 in the same direction. A plurality of first coils 421 and a plurality of second coils 422 may be provided.

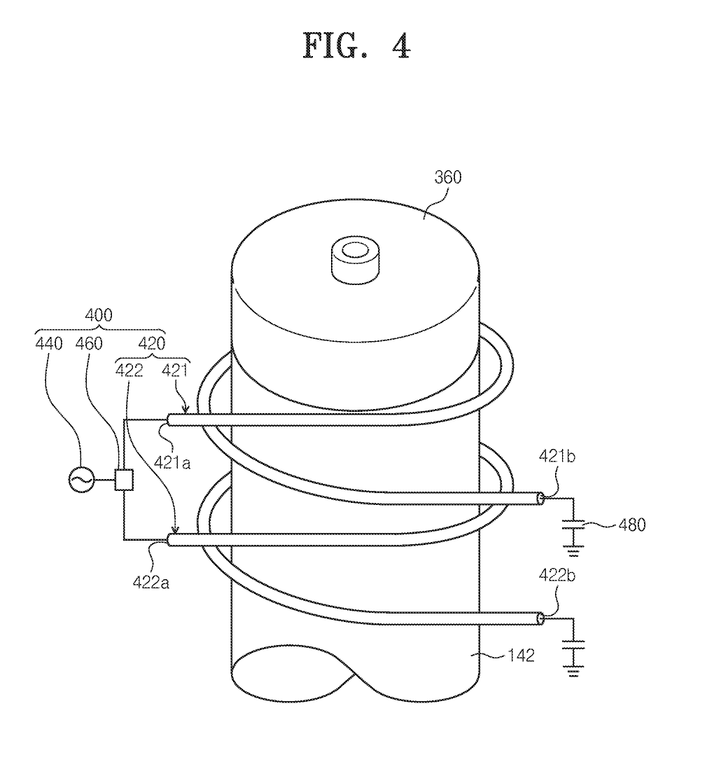

The power supply 440 applies electric power to the antenna 420. According to an embodiment, the power supply 440 may apply high-frequency power to the antenna 420. FIG. 4 is a perspective view schematically illustrating the plasma source 400 of FIG. 2. Referring to FIG. 4, for example, the power supply 440 applies high-frequency power to a first end 421a of the first coil 421 and a first end 422a of the second coil 422. A second end 421b of the first coil 421 and a second end 422b of the second coil 422 are grounded.

The connector 460 is connected to the first end 421a of the first coil 421 and the first end 422a of the second coil 422. The connector 460 distributes electric power applied by the power supply to the first coil 421 and the second coil 422. When viewed form the top, the connector 460 applies electric power such that the currents flowing through the first coil 421 and the second coil flow in the same direction. For example, the first coil 421 surrounds a side surface of the discharge chamber 142 while extending from the first end 421a connected to the connector 460 to the grounded second end 421b. The second coil 422 surrounds a side surface of the discharge chamber 142 while extending from the first end 422a connected to the connector 460 to the grounded second end 422b. When viewed from the top, the first coil 421 and the second coil 422 surround a side surface of the discharge chamber 142 in the same direction. When viewed from the top, the first coil 421 and the second coil 422 may surround a side surface of the discharge chamber 142 in the counterclockwise direction. According to an embodiment, the first end 421a of the first coil 421 may be situated to be higher than the second end 421b of the first coil 421, and the first end 422a of the second coil 422 may be situated to be higher than the second end 422b of the second coil 422.

Alternatively, selectively, the plasma source 400 may have various structures in which when viewed from the top, current flows through the first coil 421 and the second coil 422 in the same direction.

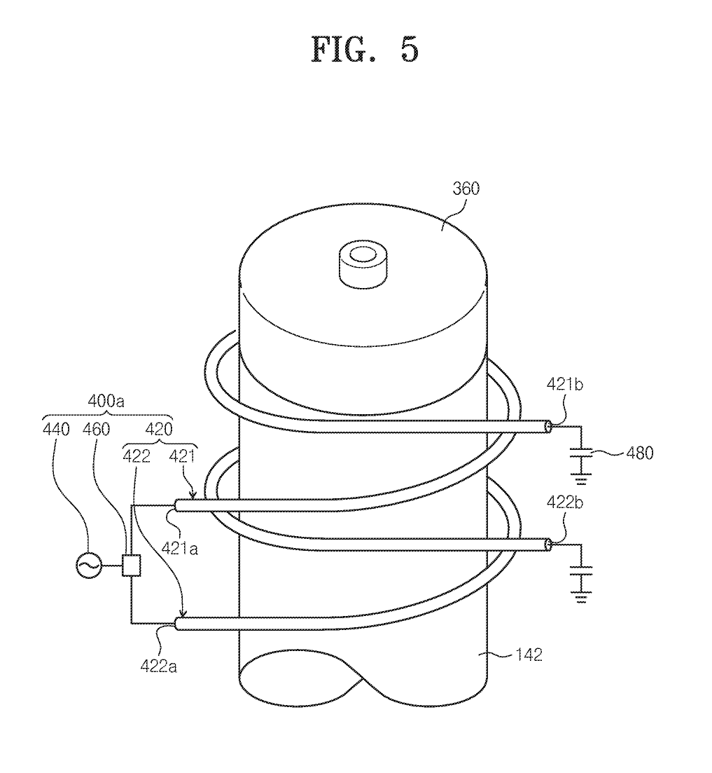

FIGS. 5 to 8 are perspective views illustrating plasma sources 400a, 400b, 400c, and 400d according to various embodiments.

Referring to FIG. 5, for example, the first end 421a of the first coil 421 may be situated to be lower than the second end 421b of the first coil 421, and the first end 422a of the second coil 422 may be situated to be lower than the second end 422b of the second coil 422. The other configurations, shapes, and structures of the plasma sources 400a are similar to those of the plasma source 400 of FIG. 4.

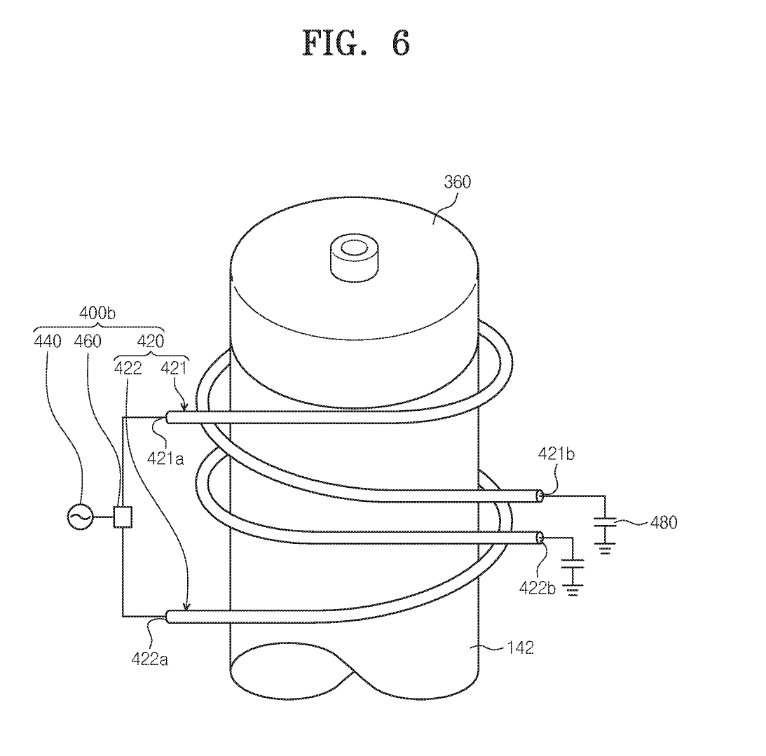

Referring to FIG. 6, for example, the first end 421a of the first coil 421 may be situated to be higher than the second end 421b of the first coil 421, and the first end 422a of the second coil 422 may be situated to be lower than the second end 422b of the second coil 422. The other configurations, shapes, and structures of the plasma sources 400b are similar to those of the plasma source 400 of FIG. 4.

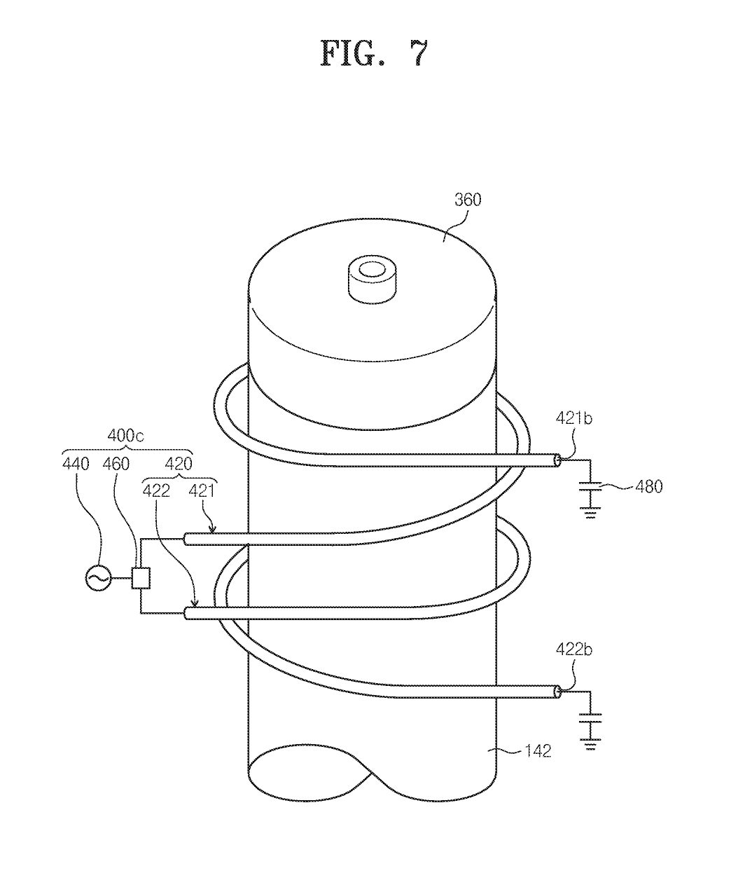

Referring to FIG. 7, for example, the first end 421a of the first coil 421 may be situated to be lower than the second end 421b of the first coil 421, and the first end 422a of the second coil 422 may be situated to be higher than the second end 422b of the second coil 422. The other configurations, shapes, and structures of the plasma sources 400c are similar to those of the plasma source 400 of FIG. 4.

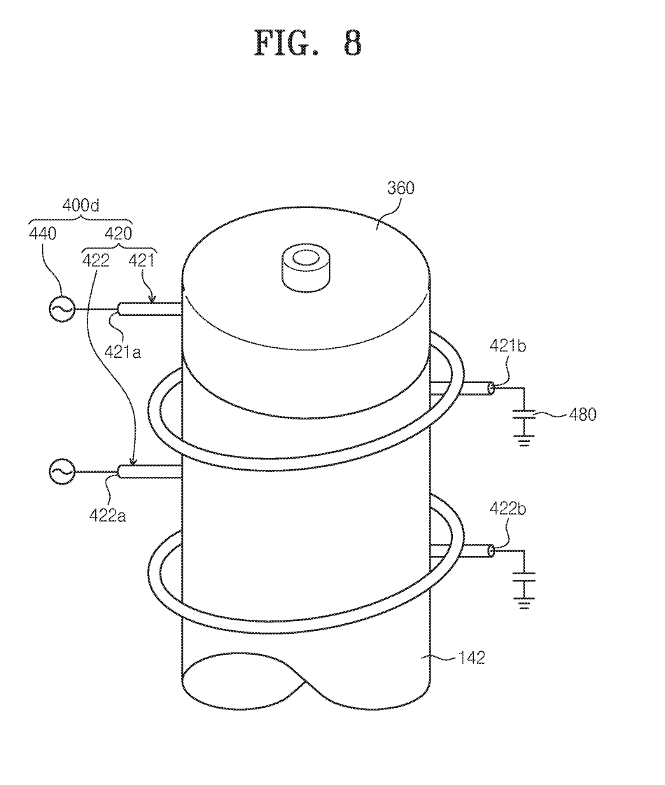

Referring to FIG. 8, unlike in FIGS. 4 to 7, a connector 460 is not provided, and separate power supplies 440 may be provided in the first coil 421 and the second coil 422. Further, the first coil 421 and the second coil 422 may surround a side surface in the clockwise direction. The other configurations, shapes, and structures of the plasma sources 400d are similar to those of the plasma source 400 of FIG. 4.

Unlike in FIGS. 4 to 8, when viewed from the top, the first coil 421 and the second coil 422 may surround a side surface in opposite directions. In this case, when viewed from the top, in order to make the directions of the currents flowing through the first coil 421 and the second coil 422 identical, electric power may be applied to the first end 421a of the first coil 421, the second end 421b of the first coil 421 may be grounded, the first end 422a of the second coil 422 may be grounded, and electric power may be applied to the second end 422b of the second coil 422. In this case, the other configurations, shapes, and structures of the plasma sources are similar to those of the plasma source 400 of FIG. 4.

Selectively, in the other embodiments than those of FIGS. 4 to 8, the plasma source 4 may have various structures in which when viewed from the top, current flows through the first coil 421 and the second coil 422 in the same direction.

As in FIGS. 4 to 8, according to an embodiment, when a power supply is connected to the first ends 421a and 422a of the first coil 421 and the second coil 422 and the second ends 421b and 422b of the first coil 421 and the second coil 422 are grounded, the second end 421b of the first coil 421 and the second end 422b of the second coil may be provided with capacitors. When the capacitors 480 are provided, the first coil 421 and the second coil 422 may be grounded through the capacitors 480. The capacitors 480 provided in the first coil 421 and the second coil 422 contribute to a balance of high-frequency power.

As described above, because the first coil 421 and the second coil 422 are connected in parallel to the power supply 440, the voltages of the electric power applied to the first coil 421 and the second coil 421 are low and the currents of the electric power applied to the first coil 421 and the second coil 422 are high when the same electric power is applied to the antenna 420, as compared with the case in which the antenna is provided with a single coil. Further, because the currents flow in the same direction when viewed from the top, a magnetic field by the electric power applied to the first coil 421 and a magnetic field by the electric power applied to the second coil 422 are not offset. Accordingly, because the same electric power having a low voltage is applied as compared with the case in which an antenna is provided with a single coil, the intensity of an electric filed by the electric power applied to the antenna 420 is low so that the inner surface of the discharge chamber 142 may be prevented from being damaged by the plasma influenced by the electric field and thus particles generated due to the damage of the inner surface of the discharge chamber 142 also may be minimized. Further, because the same electric power having a high current is applied as compared with the case in which an antenna is provided with a single coil, the intensity of a magnetic field by the electric power applied to the antenna 420 becomes higher so that the efficiency of generating plasma increases and thus the efficiency of processing a substrate increases.

Referring back to FIG. 1, the baffle 500 is situated over the substrate support unit 200. For example, the baffle 500 is provided at a lower end of the diffusion chamber 144. The plasma is supplied from the diffusion chamber 144 into the treatment chamber 120 through an injection hole 530.

The baffle 500 has a diameter that is larger than an inner diameter of a lower end of the diffusion chamber 144. The baffle 500 is grounded. According an example, the baffle 500 may contact the chamber to be grounded through the chamber 100. Selectively, the baffle 500 may be directly connected to a separate ground line. The baffle 500 may have a disk shape.

A plurality of injection holes 530 that extend from an upper end to a lower end of the baffle 500 are formed in the baffle 500. The injection holes 530 may be arranged in areas of the baffle 500 at the same density and may have the same diameter. Selectively, the injection holes 530 may have different diameters for the areas of the baffle 500.

The substrate treating apparatus 1 may further include a Faraday shield 600. The Faraday shield 600 shields a portion of an electric field applied to the discharge chamber 142 by the electric power applied to the antenna 420. The Faraday shield 600 surrounds a side surface of the discharge chamber 142 between the discharge chamber 142, and the first coil 421 and the second coil 422. The vertical length of the Faraday shield 600 corresponds to a length of the area of the first coil 421 and the second coil 422, which surrounds the side surface of the discharge chamber 142. The Faraday shield 600 may be grounded through the chamber 100. Selectively, the Faraday shield 600 may be directly connected to a separate ground line. The Faraday shield 600 may be formed of a metallic material to shield an electric field. For example, the Faraday shield 600 may be formed of a copper (Cu) material.

According to an embodiment of the inventive concept, damage to a chamber by plasma can be minimized.

Further, according to an embodiment of the inventive concept, generation of particles can be restrained.

Further, according to an embodiment of the inventive concept, an efficiency of generating plasma can be increased.

What is claimed is:

1. An apparatus for treating a substrate, the apparatus comprising:
a process chamber that has a treatment space for treating the substrate in the interior thereof;
a substrate support unit that supports the substrate in the treatment space;
a gas supply unit that supplies a gas into the treatment space; and
a plasma source that excites the gas supplied by the gas supply unit into plasma,
wherein the process chamber comprises a discharge chamber that is provided over the substrate support unit and has a space in which the gas is excited into the plasma,
wherein the plasma source comprises:
an antenna comprising a first coil and a second coil that surround a side surface of the discharge chamber along a circumference of the discharge chamber; and
a power supply that applies electric power to the antenna, and
the first coil and the second coil are alternately arranged along a vertical direction, and when viewed from the top, currents flow through the first coil and the second coil in the same direction.

2. The apparatus of claim 1, wherein the power supply applies electric power to a first end of the first coil and a first end of the second coil.

3. The apparatus of claim 2, wherein a second end of the first coil and a second end of the second coil are grounded.

4. The apparatus of claim 3, wherein the plasma source further comprises a connector that is connected to the first end of the first coil and the first end of the second coil to distribute electric power applied from the power source to the first coil and the second coil.

5. The apparatus of claim 4, wherein capacitors are provided at the second end of the first coil and the second end of the second coil, respectively, and the first coil and the second coil are grounded through the capacitors.

6. The apparatus of claim 3, wherein the first end of the first coil is situated to be higher than the second end of the first coil, and the first end of the second coil is situated to be higher than the second end of the second coil.

7. The apparatus of claim 3, wherein the first end of the first coil is situated to be lower than the second end of the first coil, and the first end of the second coil is situated to be lower than the second end of the second coil.

8. The apparatus of claim 3, wherein the first end of the first coil is situated to be higher than the second end of the first coil, and the first end of the second coil is situated to be lower than the second end of the second coil.

9. The apparatus of claim 3, wherein the first end of the first coil is situated to be lower than the second end of the first coil, and the first end of the second coil is situated to be higher than the second end of the second coil.

10. The apparatus of claim 1, wherein the first coil comprises a plurality of coils and the second coil comprises a plurality of coils.

11. The apparatus of claim 1, further comprising:
a Faraday shield that is provided between the discharge chamber, and the first coil and the second coil.

12. A plasma source for exciting a gas supplied into a treatment space in which a substrate is treated into plasma, the plasma source comprising:
an antenna comprising a first coil and a second coil that surround a side surface of a discharge chamber along a circumference of the discharge chamber having a space for exciting the gas into plasma in the interior thereof; and
a power supply that applies electric power to the antenna,
wherein the first coil and the second coil are alternately arranged along a vertical direction, and when viewed from the top, currents flow through the first coil and the second coil in the same direction.

13. The plasma source of claim 12, wherein the power supply applies high-frequency electric power to a first end of the first coil and a first end of the second coil.

14. The plasma source of claim 13, wherein a second end of the first coil and a second end of the second coil are grounded.

15. The plasma source of claim 14, further comprising:
a connector that is connected to the first end of the first coil and the first end of the second coil to distribute electric power applied from the power source to the first coil and the second coil.

16. The plasma source of claim 15, wherein capacitors are provided at the second end of the first coil and the second end of the second coil, respectively, and the first coil and the second coil are grounded through the capacitors.

17. The plasma source of claim 14, wherein the first end of the first coil is situated to be higher than the second end of the first coil, and the first end of the second coil is situated to be higher than the second end of the second coil.

18. The plasma source of claim 14, wherein the first end of the first coil is situated to be lower than the second end of the first coil, and the first end of the second coil is situated to be lower than the second end of the second coil.

19. The plasma source of claim 14, wherein the first end of the first coil is situated to be higher than the second end of the first coil, and the first end of the second coil is situated to be lower than the second end of the second coil.

20. The plasma source of claim 14, wherein the first end of the first coil is situated to be lower than the second end of the first coil, and the first end of the second coil is situated to be higher than the second end of the second coil.

21. An apparatus for treating a substrate, the apparatus comprising:
a process chamber that has a treatment space for treating the substrate in the interior thereof;
a substrate support unit that supports the substrate in the treatment space;
a gas supply unit that supplies a gas into the treatment space; and
a plasma source that excites the gas supplied by the gas supply unit into plasma,
wherein the process chamber comprises a discharge chamber that is provided over the substrate support unit and has a space in which the gas is excited into the plasma,
wherein the plasma source comprises:
an antenna comprising a first coil and a second coil that surround a side surface of the discharge chamber along a circumference of the discharge chamber; and
a power supply that applies electric power to the antenna,
wherein the first coil surrounds a side surface of the discharge chamber while extending from a first end to a second end thereof,
wherein the second coil surrounds a side surface of the discharge chamber while extending from a first end to a second end thereof, and
wherein the first coil and the second coil surrounds a side surface of the discharge chamber in the same direction when viewed form the top, and the electric power of the power supply is applied from the first end of the first coil and the first end of the second coil.

22. The apparatus of claim 21, wherein the plasma source further comprises a connector that is connected to the first end of the first coil and the first end of the second coil to distribute the electric power of the power source to the first coil and the second coil.

23. The apparatus of claim 22, wherein the second end of the first coil and the second end of the second coil are grounded.

24. The apparatus of claim 23, wherein capacitors are provided at the second end of the first coil and the second end of the second coil, respectively, and the first coil and the second coil are grounded through the capacitors.

25. The apparatus of claim 21, wherein the first end of the first coil is situated to be higher than the second end of the first coil, and the first end of the second coil is situated to be higher than the second end of the second coil.

26. The apparatus of claim 21, wherein the first end of the first coil is situated to be lower than the second end of the first coil, and the first end of the second coil is situated to be lower than the second end of the second coil.

27. The apparatus of claim 21, wherein the first end of the first coil is situated to be higher than the second end of the first coil, and the first end of the second coil is situated to be lower than the second end of the second coil.

28. The apparatus of claim 21, wherein the first end of the first coil is situated to be lower than the second end of the first coil, and the first end of the second coil is situated to be higher than the second end of the second coil.

29. The apparatus of claim 21, wherein the first coil comprises a plurality of coils and the second coil comprises a plurality of coils, and the coils of the first coil and the coils of the second coil are provided to be alternately arranged in a vertical direction.
